(19) United States
(12) Patent Application Publication
(10) Pub. No.: US 2026/0203467 A1
(43) Pub. Date: Jul. 16, 2026

(54) CARBON DIOXIDE WELL INJECTION SIMULATION TECHNIQUES

(71) Applicant: Schlumberger Technology Corporation, Sugar Land, TX (US)

(72) Inventors: Lei Jiang, Cambridge, MA (US); William Bailey, Cambridge, MA (US); Peter Tilke, Cambridge, MA (US); Florian Hollaender, Cambridge, MA (US); Romain Prioul, Cambridge, MA (US)

(21) Appl. No.: 19/441,987

(22) Filed: Jan. 7, 2026

Related U.S. Application Data
(60) Provisional application No. 63/742,620, filed on Jan. 7, 2025.

(51) Int. Cl. G06F 30/20; B65G 5/00

(52) U.S. Cl. CPC G06F 30/20; B65G 5/00

(57) ABSTRACT

Techniques for simulating carbon dioxide injection into a saline aquifer. The techniques include obtaining geological reference data that is correlated to a saline aquifer formation layer and establishing a set of carbon dioxide injection parameters to be tested. The simulation is computationally practical and efficient by mathematically partitioning the aquifer formation layer into a plurality of discrete partitions based on the geological reference data and utilizing fast analytical solutions to obtain relevant properties of interest within each partition. Thus, estimating carbon dioxide flow characteristics for each discrete partition of the plurality may take place based on the geological reference data and the carbon dioxide injection parameters.

### PRIORITY CLAIM/CROSS REFERENCE TO RELATED APPLICATION(S)

This Patent Document claims priority under 35 U.S.C. § 120 to U.S. App. Ser. No. 63/742,620, entitled “METHODS FOR FAST SIMULATION OF CARBON DIOXIDE INJECTION INTO A BRINE AQUIFER”, filed on Jan. 7, 2025 and incorporated herein by reference in its entirety.

### BACKGROUND

Injecting carbon dioxide (CO₂) into deep saline aquifers represents a critical strategy for long-term geological storage of greenhouse gases. Saline aquifers are porous and permeable formations saturated with brine, which are typically located at depths where pressures and temperatures allow CO₂ to remain in a dense phase, improving storage efficiency. For safe containment, these aquifers are commonly overlain by an impermeable cap rock—commonly referred to as an aquitard—that acts as a seal to prevent upward migration of CO₂. In addition to this primary sealing feature, geological constraints such as the absence of open or potentially open faults, fractures, and other discontinuities are other common characteristics that may help to minimize leakage risk. Along these lines, site selection for CO₂ storage generally also accounts for potential faults and fractures that might be present which could connect to shallower formations and compromise containment.

Beyond geological considerations, practical business factors strongly influence the viability of a CO₂ storage project. Cost minimization and operational efficiency are paramount. Proximity to major CO₂ sources reduces transportation costs and simplifies logistics. Ideal candidates include sites near industrial emitters such as cement plants, steel mills, paper mills, power generation facilities, chemical plants, and refineries. Locating injection sites near these emitters enables direct pipeline connections and reduces the need for costly compression and transport infrastructure.

Depth selection is another factor to consider. For example, the shallower the target aquifer the greater the reduction in drilling and completion costs. At the same time, sufficient depth may help to avoid interference with freshwater aquifers or zones used for agriculture and/or municipal water supplies. Indeed, regulatory frameworks often require a significant vertical separation between the injection zone and potable water formations to ensure environmental protection.

With the above in mind, existing wells in mature or abandoned oil or gas fields can offer economic advantages by reducing the need for new drilling. These wells may serve as injection or monitoring points, leveraging prior investments in infrastructure and subsurface characterization. However, their presence may also introduce additional risk. For example, abandoned or poorly sealed wells can act as leakage pathways for injected CO₂. Therefore, comprehensive integrity assessments and remediation plans may be undertaken to mitigate these risks.

Other considerations include reservoir heterogeneity, which affects CO₂ plume migration and pressure distribution, and the availability of geological data. Saline aquifers often lack detailed characterization because they were historically bypassed during hydrocarbon exploration. This uncertainty underscores the importance of advanced simulation techniques to predict flow behavior, pressure evolution, and containment performance under various injection scenarios.

In summary, successful CO₂ storage in saline aquifers involves balancing geological suitability with economic practicality. Selected sites should combine robust containment features—such as impermeable cap rocks and fault-free geometries—with logistical advantages like proximity to industrial emitters and existing infrastructure. Addressing these technical and business constraints through rigorous site screening and simulation may ensure safe, cost-effective, and scalable carbon sequestration.

With the above uncertainties in mind, proposals for modeling homogeneous reservoirs or aquifers have been proposed. However, these proposals tend to presume constant porosity and permeability characteristics for these reservoirs. Unfortunately, the reality is that the targeted saline aquifer is likely to be heterogenous in such porosity and permeability characteristics from one location to another along the same reservoir. Thus, the usefulness in modeling and predicting the overall capacity of a given saline reservoir in terms of carbon dioxide capacity remains limited.

### SUMMARY

An embodiment of the present disclosure described herein is directed at a method of simulating carbon dioxide injection into a saline aquifer. The method includes obtaining geological reference properties characterizing a saline aquifer formation and establishing a set of carbon dioxide injection parameters for simulation. The saline aquifer may then be mathematically partitioned into a plurality of discrete partitions based on the geological reference data. Thus, estimating carbon dioxide flow characteristics for each discrete partition of the plurality may take place based on the geological reference properties and the carbon dioxide injection parameters.

Another embodiment of the present disclosure described herein is a method of simulating carbon dioxide injection into a saline aquifer that includes obtaining geological reference data representing a saline aquifer formation and establishing a set of carbon dioxide injection parameters for simulation. The method further includes mathematically partitioning the saline aquifer formation into a plurality of discrete partitions based on the geological reference data and locating at least one point of interest within at least one of the discrete partitions. In this manner, estimating carbon dioxide flow characteristics for each discrete partition of the plurality may ensue based on the geological reference data and the carbon dioxide injection parameters. The estimating includes ascertaining a carbon dioxide flow characteristic at the points of interest at a given point in time related to the carbon dioxide injection parameters. The method enables rapid generation of a large number of CO₂ injection models (realizations) that capture the uncertainties in reservoir properties and model parameters. This is critical for risk and uncertainty modeling of CO₂ sequestration strategies. Through fast simulation, probabilistic models are quickly generated, providing improved insight into the risk and uncertainty associated with a particular CO₂ injection strategy.

In still another embodiment of the present disclosure described herein is an operation field arrangement. The arrangement includes at least one injection well at an operation field having a saline aquifer formation and a control unit for running a simulation of carbon dioxide injection into the aquifer. The control unit is configured to run a simulation, wherein the simulation includes obtaining geological reference data correlated to the saline aquifer formation layer and accounting for a set of carbon dioxide injection parameters for the simulation. The saline aquifer formation layer is mathematically partitioned into a plurality of discrete partitions based on the geological reference data for estimating carbon dioxide flow characteristics for each discrete partition of the plurality based on the geological reference data and the carbon dioxide injection parameters.

### BRIEF DESCRIPTION OF THE DRAWINGS

The appended figures illustrate only exemplary embodiments and are therefore not to be considered limiting of the scope of the disclosure, as the disclosure may admit to other equally effective embodiments.

FIG. 1 is a chart depicting a mathematically partitioned saline aquifer formation layer guided by geological reference data correlated to the formation layer.

FIG. 2 is an overview depiction of a geological system with formation layers that include the saline aquifer of FIG. 1.

FIG. 3 is a chart depicting the mathematically partitioned saline aquifer formation layer of FIG. 1 highlighting a partition of combined prism and cuboid portions.

FIG. 4A is a schematic perspective view of the prism portion utilized in constructing the highlighted partition of FIG. 3.

FIG. 4B is a schematic perspective view of the cuboid portion utilized in constructing the highlighted partition of FIG. 3.

FIG. 5 is a flow-chart summarizing an embodiment of mathematically partitioning a saline aquifer formation layer to simulate injection of carbon dioxide into the aquifer formation layer.

FIG. 6 is a schematic illustration of CO₂ flow across two different modules, where sub-figure (3) represents a CO₂ plume distribution in Edge i and Edge i+1 in dimensional scale and sub-figures (1) and (2) show the CO₂ plume distribution in the dimensionless domain for Edge i and Edge i+1, respectively.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following description, numerous details are set forth to provide an understanding of the present disclosure. This includes description of the surrounding environment in which embodiments detailed herein may be utilized. Additionally, it will be understood by those skilled in the art that the embodiments described may be practiced without these and other particular details. Further, numerous variations or modifications may be employed which remain contemplated by the embodiments as specifically described.

Embodiments are described with reference to certain techniques for simulating carbon dioxide injection to a saline aquifer geological formation. For example, an illustrative embodiment of the application details the simulation of such an injection in an offshore environment. The techniques include establishing injection parameters for the carbon dioxide and correlating certain geological reference data to the formation layer. Thus, mathematically partitioning the formation layer into discrete partitions for analysis and estimating of carbon dioxide flow characteristics may be undertaken in a practical manner. Of course, these techniques may be applied to any number of operation field types including in the onshore environment. Indeed, so long as a practical mathematical partitioning takes place employing geological reference data correlated to the saline aquifer formation for sake of the simulating, appreciable benefit may be realized.

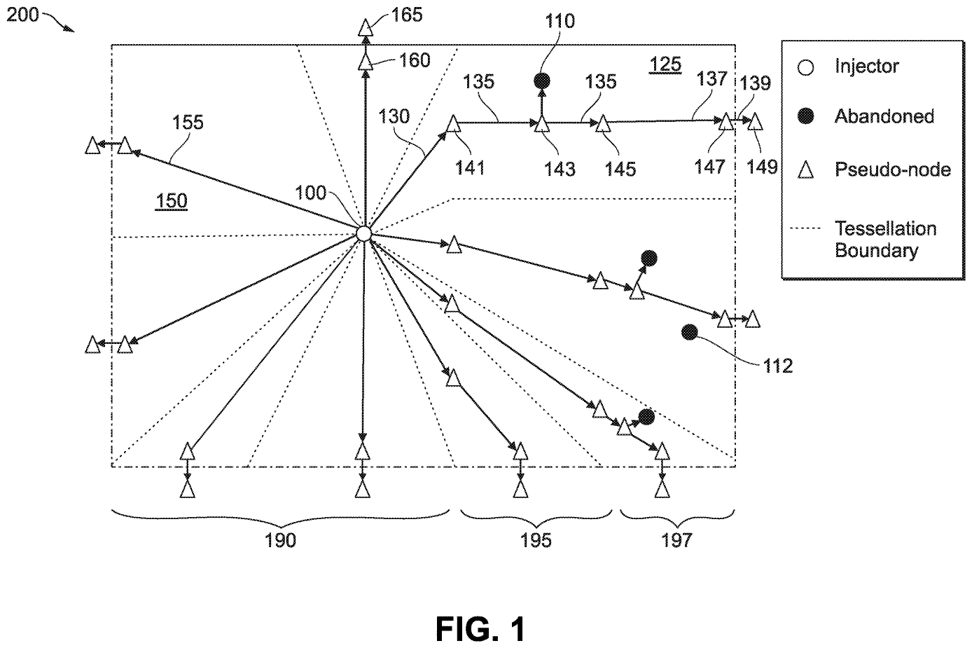

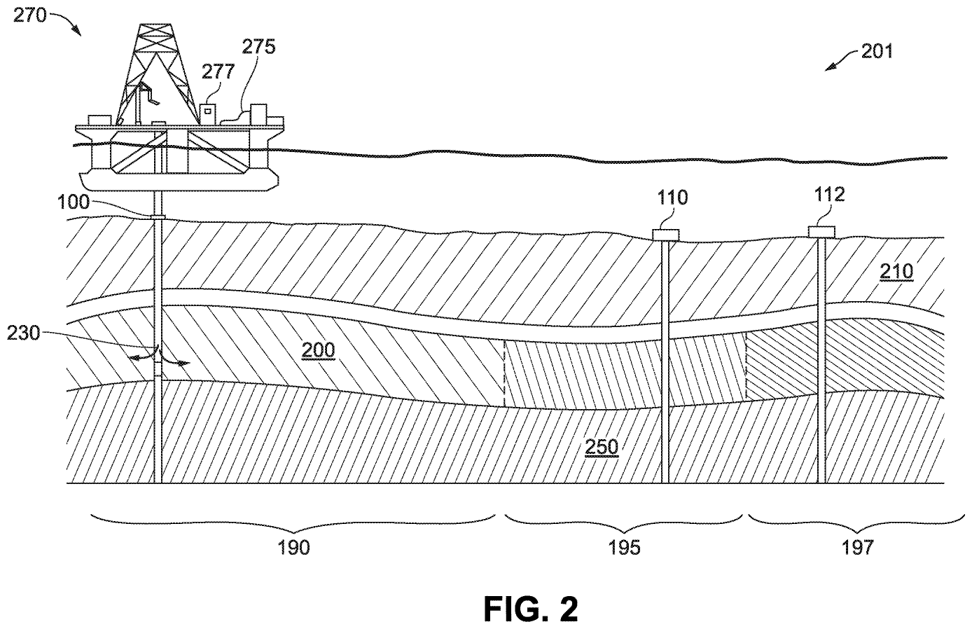

Referring specifically now to FIG. 1, a chart depicting a mathematically partitioned saline aquifer formation layer is shown. This saline aquifer formation layer 200 is illustrated as part of the overview shown in FIG. 2. Nevertheless, the chart of FIG. 1 is presented as a planar top view of this formation layer 200 with an injection well 100 near the center of the layout. It is this location to which carbon dioxide waste might be pumped or injected to the aquifer formation layer 200. Thus, simulating how such flow might occur in advance of the carbon dioxide delivery may be of benefit. For example, note that apart from the injection well 100, other abandoned wells 110, 112 are also present. It is of note that for ease of illustration, the chart of FIG. 1 depicts a single injection well 100 along with multiple abandoned wells (e.g. 110 and 112). However, carbon dioxide injection simulation and any follow-on injection may employ multiple injections wells. By the same token, the environment may present no abandoned wells. Regardless, depending on the amount of carbon dioxide to be delivered and/or potential pressures that might result, the formation layer 200 may or may not be a good candidate location for carbon dioxide storage. Keeping with reference to the scenario depicted in FIG. 1, this may also depend on the structural integrity of these abandoned wells 110, 112. Of course, even apart from these wells 110, 112 and their potential leak tolerances or profiles, the formation layer 200 may have other limitations or potential leak points itself. For example, the overall carbon dioxide storage capacity of the aquifer formation layer 200 is a primary factor in determining whether this layer 200 is a suitable candidate for the anticipated carbon dioxide storage, regardless of the presence of any abandoned wells 110, 112. By way of specific example, where 20 million metric tons of carbon dioxide waste is to be dealt with but the aquifer formation layer 200 might only accommodate 2 million metric tons of carbon dioxide waste, the effort necessary to inject and deliver only a small portion of the waste may render the formation layer 200 a poor candidate option for the carbon dioxide storage.

For the embodiment illustrated in FIG. 1, simulating the carbon dioxide delivery, to determine whether the aquifer formation layer 200 is a good candidate for the carbon dioxide storage involves a mathematical partitioning of the formation layer 200 to facilitate a more practical cumulative analysis. For example, note the Voronoi-type tessellation boundaries ( - - - ) that emanates from the site of the injection well 100. By way of specific example, these boundaries ( - - - ) define nine different partitions, e.g. 125, 150 radiating out from the injection well 100 that may be discreetly and independently analyzed. Of course, any number of partitions 125, 150 may be employed.

The partitions 125, 150 are drawn up and selected based on potential characteristics of the formation layer 200. For example, the top right partition 125 may be drawn up based on a first presumed permeability and porosity characteristics at this area of the formation. On the other hand, the top left partition 150 may be drawn up and selected based on a second, different presumed permeability and porosity characteristics. For example, perhaps the top left partition 150 is presumed to display a consistent and greater porosity and permeability than that of the top right partition 125. Thus, in this example, a carbon dioxide flow 155 through the top left partition 150 may proceed with greater ease and at a greater rate than a carbon dioxide flow 130, 135, 137 through the top right partition 125. Thus, different pressure and saturation profiles may be displayed at the top right partition 125 as compared to the top left partition 150. Of course, this is only exemplary and these concepts are discussed in greater detail below. Further, the tessellation or partitioning may be presented in different formats than that depicted. For example, each of the nine partitions (including 125 and 150) may emanate from the injection well 100 at a uniform angle of 40°.

With continued added reference to FIG. 2, the above-described partitioning as illustrated may be guided by geological reference data that is correlated to the formation layer 200. For example, recall that the layout of the operation field 201 may have originally been designed with hydrocarbon production from various wells 100, 110, 112 in mind. This means that during design, appraisal and subsequent drilling operations a host of well logging information has been acquired and likely stored. Thus, even though the aquifer formation layer 200 was not the target of production operations, it was likely evaluated to some degree just like other adjacent formation layers 210, 250. This means that seismic data, geological maps or logging data obtained through any of the wells 100, 110, 112 may constitute pertinent geological reference data that might be correlated to the aquifer formation layer 200 which is now of particular interest. Once more, even outside of the illustrated operation field 201, adjacent geological formations, perhaps further away but similarly comparable, may render available reference data. Similarities that are pertinent for referencing may include characteristics of porosity, permeability, pressures, geometries of the saline aquifer formation and aquitard or fluid properties such as density, viscosity and relative permeability.

Whatever the case, once suitable geological reference data is identified, it may be used in making correlations to the aquifer formation layer 200. Thus, guidance is available to help draw up the different partitions (e.g. 125, 150 and others) as illustrated in FIG. 1.

Referring specifically now to FIG. 2, an overview depiction of an operation field 201 is shown with formation layers 210, 200, 250 that include the saline aquifer formation layer 200 of FIG. 1. While the depicted wells 110, 112 were drilled and completed with hydrocarbon production operations in mind, focus is now drawn to the possibility of drilling an injection well 100 to inject carbon dioxide into the aquifer formation layer 200 (see arrows 230).

In the example shown, the operation field 201 is offshore and the carbon dioxide waste may be brought to a platform 270. Note the illustration of an injection pump 275 at the platform 270 along with a control unit 277 which may be used to direct a variety of operations, perhaps even including the simulation techniques described herein. Of course, the techniques described herein may be carried out in other manners by way of other equipment and even at onshore operation field locations. Regardless, as part of the simulating of carbon dioxide delivery under consideration, certain injection parameters may be established for consideration. For example, in thinking of the flowing carbon dioxide 230, injection parameters of flowrate, duration, overall volume and the pressure of the supply may be set and considered. Thus, returning briefly with reference to FIG. 1, the flow 230 shown in FIG. 2 may be evaluated on a partition by partition basis (e.g. recall the top left flowline 155 versus the top right flowline 130 emanating from the injection well 100 as shown in FIG. 1).

Returning with reference to FIG. 1, the simulated different flowlines 155, 130, emanating from the injector well 100 proceed through different partitions 150, 125 and encounter different presumed formation characteristics, depending on the partition (150 or 125) at hand. As indicated above, in the illustrated example, the top left partition 150 may have comparatively greater porosity and permeability characteristics. In this illustrative example, notice that this partition 150 may exist entirely within a first region 190 of the formation layer 200 perhaps predominantly of a first type of rock. Notice the depiction of this region 190 at FIG. 2 as well. Alternatively, the top right partition 125 may include some of this first region 190 but may also traverse a second region 195 where the rock character changes and even to a third region 197 where the rock character further changes. Again, these regions 190, 195, 197 are also depicted at the overview of FIG. 2 (e.g. note the vertical dashed lines separating the relative regions 190, 195, 197 from one another at FIG. 2).

Continuing with reference to FIG. 1, notice that there are a variety of points of interest which are plotted and referred to herein as pseudo-nodes (4). For example, with reference to the top right partition 125 notice that the initially plotted flowline 130 from the injector well 100 reaches a particular pseudo-node 141 which is located at the boundary of the first rock-type region 190 and the second region 195. So, for example, pressure, carbon dioxide saturation at a given point in time following the start of injection or other characteristics of the carbon dioxide delivery may be of particular interest at this location. That is, unlike the complete saturation at the location of the injector well 100 at the outset of the carbon dioxide delivery, saturation at any depicted pseudo-node location (4) is dependent on a variety of factors over time. Further, as the carbon dioxide flow continues through the second region 195 (via 135), another point of interest may be presented at a second pseudo-node 143. In this instance, the pseudo-node 143 is located along the flowline 135 at a point that is closest to an abandoned well 110. As suggested above, this may be of interest due to the possibility of the abandoned well 110 to present a leak point to the carbon dioxide waste that is being delivered to the aquifer formation layer 200 as described. So, for example, a pressure estimate in light of the proposed injection parameters may be of particular interest. Further, as the flowline 135 continues, another pseudo-node point of interest 145 may be presented at the boundary between the second region 195 and the third region 197. In fact, for the illustrative example shown, simulation information may be obtained at either side of the boundary between the aquifer formation layer 200 and points beyond (e.g. at pseudo-node locations 147 and 149). In fact, notice that at this boundary between pseudo-node 147 and pseudo-node 149 permeability and porosity continue to allow carbon dioxide flow (e.g. from flowline 137 to flowline 139). This is indicated by the dashed vertical line at the boundary of the aquifer formation layer 200 at this location. Alternatively, other portions of the aquifer formation layer 200 may be impermeable (as indicated by the horizontal solid line between pseudo-node 160 and pseudo-node 165 at a different partition).

Of course, as described above, the pressure and saturation values simulated for any given pseudo-node (A) at any given point in time are dependent upon two different factors. These factors firstly include the parameters of the injection at the injection well including a presumed flowrate, duration, volume and pressure of the injection and secondly, these factors include the correlated geological reference data that is employed at each partition (such as the described partitions 125 and 150). Further, each partition (e.g. 125 or 150) may presume assigned constant porosity and permeability characteristics. In this manner, providing estimated values at any given pseudo-node (A) at any given point in time following injection may be a practical undertaking. Stated another way, running the simulation to obtain these values is a matter of inputting injection parameters to be tested against permeability and porosity characteristics that have been broken down into partitions (e.g. 125, 150) that are based on geological reference data.

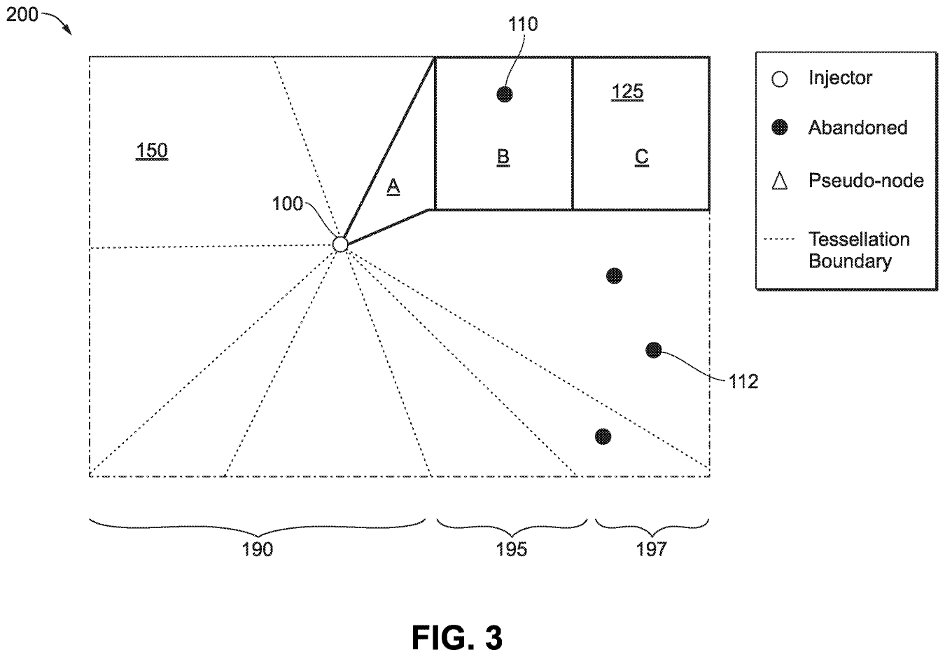

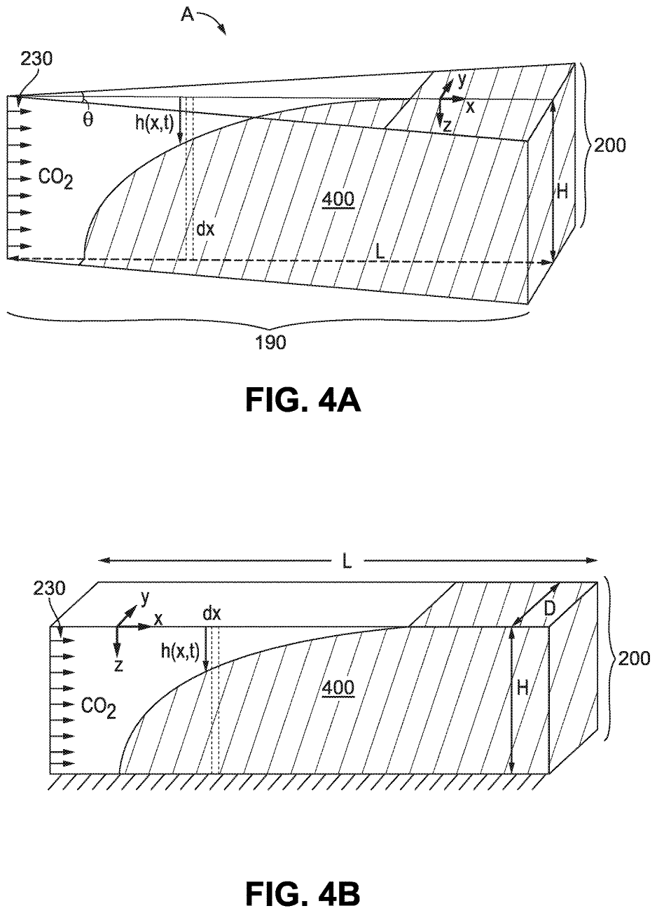

Of course there is value in the partitioning described above in terms of the correlating of geological reference data to predetermined partitions because this facilitates faster and more efficient simulations as opposed to a potentially impractical computational analysis in absence of the illustrated and described partitioning. However, there is also an efficiency in the determining of the partitions themselves. For example, notice that the partitions are presented as general platonic shapes of well-known canonical proportions. With more specific reference to FIGS. 3, 4A and 4B, below, the advantage of utilizing these types of predefined shapes for this tessellating or partitioning is described in further detail.

Referring specifically now to FIG. 3, a chart depicting the mathematically partitioned saline aquifer formation layer of FIG. 1 is shown. That is, in terms of the injection well 100 and the partition (e.g. 125, 150). The chart is the same as that of FIG. 1. However, in this view, the partitioning of the top right partition 125 is further highlighted. More specifically, this partition 125 is made up of a combination of prism A, cuboid B and cuboid C portions. Alternatively, the top left partition 150 is made up of a single prism morphology. As used herein, the term “prism” may encompass other triangular three-dimensional shapes and the term “cuboid” may include rectangular and trapezoidal shapes as well. That is, these terms are only meant to be descriptive of commonly understood platonical or canonical shapes and are not meant to infer any further limiting characteristic. In fact, in one embodiment, a database of such shapes may be available at the control unit 277 of FIG. 2 or other suitable location from which the simulation techniques described herein may be run. By using such readily available shapes in developing the simulation protocol for application to the aquifer formation layer 200 and proposed injection parameters, computational resources may be kept to a minimum and manageable level for obtaining relatively quick simulation results.

As suggested further above, utilizing conventional platonic shapes, such as a prism A or a cuboid B or C, to make up a given partition means that readily understood and calculatable geometries and areas are available to work with. So, for example, for the top right partition 125, geological reference data in terms of permeability and porosity may be applied across a platonic shape prism A and across another two platonic shapes cuboid B and C with readily determinable areas. With specific reference to FIGS. 4A and 4B, note the dimensional variables that are illustrated for each platonic shape (A, B and C). Furthermore, note the potential influx of the carbon dioxide flow 230. This is the same pumped flow 230 initially illustrated in FIG. 2 from which the flowlines of FIG. 1 (e.g. 130, 155) are drawn. Regardless, from a computational standpoint, geological characteristic reference data may now be applied across a predetermined platonic shape area with known carbon dioxide pump injection parameters applied thereto for sake of fast and practical simulation. In sum, with such reference data applied to a known platonic shape combination in light of injection parameters to be tested, a quick and practical estimation of pressure and saturation within the partition 125 at a given point in time may readily be simulated. In keeping with the illustrated example of FIG. 3, this may be of significance where an abandoned well 110 is present within the partition 125 at hand for which potential pressure exposures and leak tolerances may be under consideration.

Referring specifically now to FIG. 4A, a schematic perspective view of the prism portion A utilized in constructing the highlighted partition 125 of FIG. 3 is shown. As with the entire top left partition 150 of FIGS. 1 and 3, the entirety of this portion A is found within a first region 190 of a given rock type of the aquifer formation layer 200 whereas the other portions B or C of FIG. 3 may be represented at FIG. 4B which includes other rock type regions (e.g. see 195 or 197 of FIG. 3). Partitioning may be based on properties variations such as illustrated above or on geometrical considerations, abstracting structural variations into one of the existing canonical shapes along which flow characteristics can be computed. This may lead to calculating the area of the formation layer 200 subject to these applied reference data characteristics by breaking it up into multiple parts for the cuboid portions of the partition 125 of FIG. 3. That is, the representation of FIG. 4B may be applicable to either section B or C of FIG. 3. By the same token, for the illustration of FIG. 4A volume may be determined for the portion A that is shown which is subject to the injection parameters of the carbon dioxide flow 230. Further, note that displaceable water or saline 400 is shown that may interact with or take on some of the carbon dioxide inflow 230.

Moving to FIG. 4B, the same principles are applied. Specifically, as noted above FIG. 4B illustrates a schematic perspective view of the cuboid portion B or C utilized in constructing the highlighted partition 125 of FIG. 3. Thus, it is true that the area determination variables are presented differently because the portions (B or C) are cuboid shape unlike the prism shape of portion A. However, the cuboid portion B or C is subject to the same inflow of carbon dioxide (arrows 230) which may still eventually reach, interface and potentially displace water or saline 400 of the formation layer 200. Further, the characteristics of the portions A, B and C in terms of porosity and permeability are assigned based on the employed geological reference data in their respective regions. Thus, while the calculations are determined differently due to the dimensional shape differences, the simulated results may be considered as part of the same flow partition, subject to some continuity and generally be applied to the entirety of the partition 125 as a result of the applied injection parameters of the carbon dioxide flow 230.

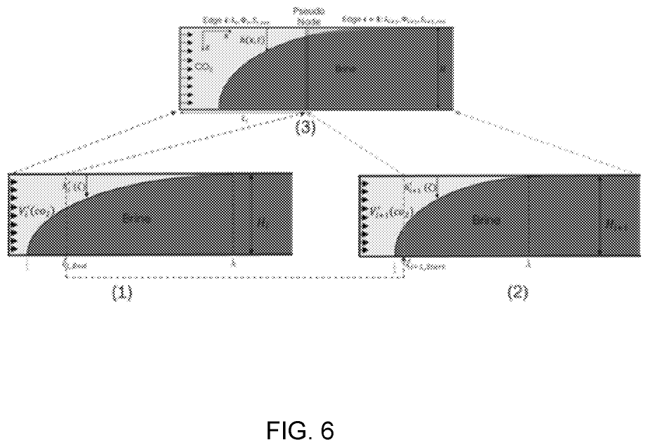

With added reference to FIG. 3, and recalling that the top right partition 125 is made up of different platonic portions A, B and C, simulations of flow across different transitions may be considered even though residing in the same partition 125. That is, recall that these portions A, B and C correspond to different regions 190, 195, 197 of the aquifer formation layer 200 and each may be of independently assigned porosity or permeability characteristics based on geological reference values as described above. This means that predicting flow and other parameters at the transition from one portion to another may be of particular value. So, for example, with particular reference to FIG. 4B, examination of injection flow from cuboid portion B to cuboid portion C may be further considered. Of course, the same may be true where a prism shape is under consideration and both are described below. Regardless, in these examples the considerations may be referred to as a flow through two different modules or edges, schematically illustrated in FIG. 6 as Edge i and Edge i+1 and presented as the three sub-figures (1), (2), and (3) shown in FIG. 6. Sub-FIG. 1) in FIG. 6 represents the actual distribution of the CO₂ plume in Edge i and Edge i+1. Sub-figures (2) and (3) in FIG. 6 show the CO₂ plume distribution in the dimensionless domain (where the dimensionless variables are defined by equations (11)-(12) for such a cuboid module (see the Equation Addendum further below)). Indeed, with further reference to the Addendum equations below, equations (22)-(23) are provided for working with a prism module).

The proposed method for calculating the CO₂ plume distribution involves the following steps:
1. Using the parameters of Edge i and Edge i+1, of FIG. 6 and the formulas provided in the Addendum below, calculate the dimensionless CO2 plume thickness

$$( {h}_{i}^{′} ( {ζ}_{i} ) , {h}_{i + 1}^{′} ( {ζ}_{i + 1} ) )$$

and accumulated volume

$$( {V}_{i}^{′} ( {ζ}_{i} ) , {V}_{i + 1}^{′} ( {ζ}_{i + 1} ) ) ,$$

as shown in rig. 6 sub-figures (2) and (3).
2. For the actual length of Edge i (x=Lᵢ), compute the corresponding dimensionless distance.
   For cuboid module:

$${( {ζ}_{i} )}_{End} = \frac{{L}_{i} {D}_{i}}{{k}_{i} {τ}_{i}} \qquad ( 1 )$$

For prism module:

$${( {ζ}_{i} )}_{End} = \frac{{( {L}_{i} )}^{2}}{{k}_{i} {τ}_{i}} \qquad ( 2 )$$

We then transform the dimensionless CO₂ plume distribution and accumulated volume into their dimensional counterparts.
3. In the dimensionless accumulated volume equation

$$( {V}_{i + 1}^{′} ( ζ ) )$$

for Edge i+1, find the dimensionless distance ζ_{i+1_Start} such that

$${V}_{i + 1}^{′} [ {( {ζ}_{i + 1} )}_{start} ] = {V}_{i}^{′} [ {( {ζ}_{i} )}_{E n d} ] \qquad ( 3 )$$

4. To maintain continuity of the CO₂ plume thickness between Edge i and Edge i+1, a pseudo-height

$${H}_{i + 1}^{*}$$

is defined for Edge i+1, such that:

$${H}_{i + 1}^{*} = \frac{{H}_{i} {h}_{i}^{′} [ {( {ζ}_{i} )}_{E n d} ]}{{h}_{i + 1}^{′} [ {( {ζ}_{i + 1} )}_{S t a r t} ]} \qquad ( 4 )$$

5. For any point on Edge i+1, calculate its actual distance to the previous pseudo-node Δxᵢ₊₁ and its corresponding dimensionless distance.
   If Edge i+1 is a cuboid module:

$${ζ}_{i + 1} = \frac{[ {( {x}_{i + 1} )}_{S t a r t} + Δ {x}_{i + 1} ] {D}_{i + 1}}{{k}_{i + 1} {τ}_{i + 1}} \qquad ( 5 )$$

$$where$$

$${( {x}_{i + 1} )}_{S t a r t} = \frac{{( {ζ}_{i + 1} )}_{S t a r t} {k}_{i + 1} {τ}_{i + 1}}{{D}_{i + 1}} \qquad ( 6 )$$

$${τ}_{i + 1} = \frac{qt}{{H}_{i + 1}^{*} {ϕ}_{i + 1} {k}_{i + 1} [ 1 - {( {S}_{r e s} )}_{i + 1} ]} \qquad ( 7 )$$

If Edge i+1 is a prism module:

$${ζ}_{i + 1} = \frac{{[ {( {x}_{i + 1} )}_{Start} + Δ {x}_{i + 1} ]}^{2}}{{k}_{i + 1} {τ}_{i + 1}} \qquad ( 8 )$$

$$where$$

$${( {x}_{i + 1} )}_{Start} = \sqrt{{( {ζ}_{i + 1} )}_{Start} {k}_{i + 1} {τ}_{i + 1}} \qquad ( 9 )$$

$${τ}_{i + 1} = \frac{qt}{{( {c}_{1} )}_{i + 1} {H}_{i + 1}^{*} {ϕ}_{i + 1} {k}_{i + 1} [ 1 - {( {S}_{r e s} )}_{i + 1} ]} \qquad ( 10 )$$

We then convert the dimensionless CO₂ plume distribution and accumulated volume into their dimensional counterparts.
   The parameters c₁, φ, k and Sᵣₑₛ are defined in Addendum below. Using this method, we can calculate the thickness distribution of the CO₂ plume as it transitions between different modules.

### Equation Addendum:

We have derived new analytical solutions for several basic modules that can be used to simulate the CO₂ saturation and pressure distribution within the modules during CO₂ injection. These solutions are based on certain assumptions such as ignoring capillary pressure effects, assuming the fluids are incompressible and immiscible, maintaining a sharp interface between CO₂ and brine, and achieving vertical equilibrium in the vertical pressure distribution.

### A. Cuboid Module

Assume the system is a brine-filled confined aquifer with cuboid shape, as shown in FIG. 4B which might be representative of B or C as shown in FIG. 3. The aquifer has a length of L, a width D, and a height of H.

An injection well is located on the left side, and CO₂ is injected with a constant flowrate q. The injected CO₂ forms an invasion front in the (x,z)-plane, with thickness h(x,t). The CO₂ plume is assumed to independent of the value of y. The CO₂ region behind the invasion front h(x,t) has brine with constant residual saturation Sᵣₑₛ. A constant pressure boundary is assumed on the right side.
We define the following dimensional parameters:

$$Δ ρ = {ρ}_{w} - {ρ}_{c} , {λ}_{c} = \frac{{k}_{r , c}}{{μ}_{c}} , {λ}_{w} = \frac{{k}_{r , w}}{{μ}_{w}} \qquad ( 11 )$$

and the following dimensionless parameters:

$$Γ = \frac{Δ ρ g {λ}_{w} k {H}^{2}}{q} , λ = \frac{{λ}_{c}}{{λ}_{w}} , τ = \frac{qt}{H ϕ k ( 1 - {S}_{r e s} )} , \qquad ( 12 )$$

$${h}^{′} = \frac{h}{H} , {V}_{co 2}^{′} = \frac{{V}_{c o 2}}{qt} , {p}^{′} = \frac{p}{Δ ρ g H} , ζ = \frac{x D}{k τ}$$

where ρ_{α} is the density of fluid α (a═c, w), k_{r,a} is the relative permeability, μ_{α} is the viscosity, k is the permeability in the horizontal direction, φ is the porosity. λ is the mobility contrast between CO₂ and brine.
If λ>1, the solution for the dimensionless CO₂ height is

$${h}^{′} ( ζ ) = \{ \begin{matrix}0 & for ζ \geq λ \\ \frac{1}{λ - 1} ( \sqrt{\frac{λ}{ζ}} - 1 ) & for \frac{1}{λ} \leq ζ < λ \\ 1 & for ζ < \frac{1}{λ}\end{matrix} \qquad ( 13 )$$

The solution for the dimensionless accumulated volume of CO₂ along ζ is

$${V}_{co 2}^{′} ( ζ ) = \{ \begin{matrix}1 & for ζ \geq λ \\ \frac{2 \sqrt{λζ} - ζ - 1}{λ - 1} & for \frac{1}{λ} \leq ζ < λ \\ ζ & for ζ < \frac{1}{λ}\end{matrix} \qquad ( 14 )$$

The solution for the dimensionless pressure is

$${p}^{′} ( ζ , τ ) = \{ \begin{matrix}{p}^{′} ( Ψ , τ ) & for ζ \geq Ψ \\ {p}^{′} ( Ψ , τ ) + \frac{1}{Γ} \frac{k τ}{{D}^{2}} ( Ψ - ζ ) & for λ \leq ζ < Ψ \\ {p}^{′} ( {α}_{1} , τ ) + {F}_{1} ( ζ , τ ) & for \frac{1}{λ} \leq ζ < {α}_{1} \\ {p}^{′} ( {α}_{2} , τ ) + \frac{1}{Γ λ} \frac{k τ}{{D}^{2}} ( {α}_{2} - ζ ) & for ζ < {α}_{2}\end{matrix} \qquad ( 15 )$$

$$Ψ = \frac{LD}{k τ} , {α}_{1} = min \{ λ , Ψ \} , {α}_{2} = min \{ \frac{1}{λ} , Ψ \} \qquad ( 16 )$$

$${F}_{1} ( ζ , τ ) = \frac{1}{Γ \sqrt{λ}} \frac{k τ}{{D}^{2}} \frac{2}{3} ( {α}_{1}^{3 / 2} - {ζ}^{3 / 2} ) - \frac{λ}{{( λ - 1 )}^{2}} [ \sqrt{\frac{λ}{ζ}} - \sqrt{\frac{λ}{{α}_{1}}} - \frac{1}{2} ln ( \frac{{α}_{1}}{ζ} ) ] \qquad ( 17 )$$

If λ≤1, the solution for the dimensionless CO₂ height is

$${h}^{′} ( ζ ) = \{ \begin{matrix}0 & for ζ \geq 1 \\ 1 & for ζ < 1\end{matrix} \qquad ( 18 )$$

The solution for the dimensionless accumulated volume of CO₂ along ζ is

$${V}_{co 2}^{′} ( ζ ) = \{ \begin{matrix}1 & for ζ \geq 1 \\ ζ & for ζ < 1\end{matrix} \qquad ( 19 )$$

The solution for the dimensionless pressure is

$${p}^{′} ( ζ , τ ) = \{ \begin{matrix}{p}^{′} ( Ψ , τ ) & for ζ \geq Ψ \\ {p}^{′} ( Ψ , τ ) + \frac{1}{Γ} \frac{k τ}{{D}^{2}} ( Ψ - ζ ) & for 1 \leq ζ < Ψ \\ {p}^{′} ( {β}_{1} , τ ) + \frac{1}{Γ λ} \frac{k τ}{{D}^{2}} ( {β}_{1} , ζ ) & for ζ < {β}_{1}\end{matrix} \qquad ( 20 )$$

$${β}_{1} = min \{ 1 , Ψ \} \qquad ( 21 )$$

### B. Prism Module

Assume the system is a brine-filled confined aquifer with prism shape, as shown in 4A. The prism aquifer has a length of L and a height of H, with an angle of θ.
An injection well is located on the left side, and CO₂ is injected with a constant flowrate q. The injected CO₂ forms an invasion front in the (x,z)-plane, with thickness h(x,t). The CO₂ plume along y direction is assumed to maintain the same shape. The CO₂ region behind the invasion front h(x,t) has brine with constant residual saturation Sᵣₑₛ. A constant pressure boundary is assumed on the right side.
Define the following dimensional parameters:

$${c}_{1} = 2 tan \frac{θ}{2} , \qquad ( 22 )$$

$$Δρ = {ρ}_{w} - {ρ}_{c} ,$$

$${λ}_{c} = \frac{{k}_{r , c}}{{μ}_{c}} ,$$

$${λ}_{w} = \frac{{k}_{r , w}}{{μ}_{w}}$$

and the following dimensionless parameters:

$$Γ = \frac{{c}_{1} Δ ρ g {λ}_{w} {kH}^{2}}{q} , \qquad ( 23 )$$

$$λ = \frac{{λ}_{c}}{{λ}_{w}} ,$$

$$τ = \frac{q t}{{c}_{1} H ϕ k ( 1 - {S}_{res} )} ,$$

$${h}^{′} = \frac{h}{H} ,$$

$${V}_{c o 2}^{′} = 2 \frac{{V}_{CO 2}}{q t} ,$$

$${p}^{′} = \frac{p}{Δ ρ gH} ,$$

$$ζ = \frac{{x}^{2}}{k τ}$$

where ρ_{α} is the density of fluid α (α═c, w), k_{r,α} is the relative permeability, μ_{α} is the viscosity, k is the permeability in the horizontal direction, φ is the porosity.
If λ>1, the solution for the dimensionless CO₂ height is

$${h}^{′} ( ζ ) = \{ \begin{matrix}0 & for ζ \geq 2 λ \\ \frac{1}{λ - 1} ( \sqrt{\frac{2 λ}{ζ}} - 1 ) & for \frac{2}{λ} < ζ < 2 λ \\ 1 & for ζ \leq \frac{2}{λ}\end{matrix} \qquad ( 24 )$$

The solution for the dimensionless accumulated volume of CO₂ along ζ is

$${V}_{co 2}^{′} ( ζ ) = \{ \begin{matrix}0 & for ζ \geq 2 λ \\ \frac{2 \sqrt{2 λζ} - ζ - 2}{λ - 1} & for \frac{2}{λ} < ζ < 2 λ \\ ζ & for ζ \leq \frac{2}{λ}\end{matrix} \qquad ( 25 )$$

The solution for the dimensionless pressure is

$${p}^{′} ( ζ ) = \{ \begin{matrix}{p}^{′} ( Ψ ) & for ζ \geq Ψ \\ {p}^{′} ( Ψ ) + \frac{1}{2 Γ} ln ( \frac{Ψ}{ζ} ) & for 2 λ \leq ζ < Ψ \\ {p}^{′} ( {α}_{3} , ) + {F}_{2} ( ζ ) & for \frac{2}{λ} < ζ < {α}_{3} \\ {p}^{′} ( {α}_{4} ) + \frac{1}{2 Γ λ} ln ( \frac{{α}_{1}}{ζ} ) & for ζ \leq {α}_{4}\end{matrix} \qquad ( 26 )$$

$$Ψ = \frac{{L}^{2}}{k τ} , {α}_{3} = min \{ 2 λ , Ψ \} , {α}_{4} = min \{ \frac{2}{λ} , Ψ \} \qquad ( 27 )$$

$${F}_{2} ( ζ ) = \frac{1}{Γ \sqrt{2 λ}} ( \sqrt{{α}_{3}} - \sqrt{ζ} ) - \frac{λ}{{( λ - 1 )}^{2}} ( \sqrt{\frac{2 λ}{ζ}} - \sqrt{\frac{2 λ}{{α}_{3}}} - \frac{1}{2} ln ( \frac{{α}_{3}}{ζ} ) ) \qquad ( 28 )$$

where
If λ≤1, the solution for the dimensionless CO₂ height is

$${h}^{′} ( ζ ) = \{ \begin{matrix}0 & for ζ \geq 2 \\ 1 & for ζ < 2\end{matrix} \qquad ( 29 )$$

The solution for the dimensionless accumulated volume of CO₂ along ζ is

$${V}_{co 2}^{′} ( ζ ) = \{ \begin{matrix}2 & for ζ \geq 2 \\ ζ & for ζ < 2\end{matrix} \qquad ( 30 )$$

The solution for the dimensionless pressure is

$${p}^{′} ( ζ ) = \{ \begin{matrix}{p}^{′} ( Ψ ) & for ζ \geq Ψ \\ {p}^{′} ( Ψ ) + \frac{1}{2 Γ} ln ( \frac{Ψ}{ζ} ) & for 2 λ < ζ < Ψ \\ {p}^{′} ( {β}_{2} ) + \frac{1}{2 Γ λ} ln ( \frac{{β}_{1}}{ζ} ) & for ζ \leq {β}_{2}\end{matrix} \qquad ( 31 )$$

$${β}_{2} = min \{ 2 , Ψ \} \qquad ( 32 )$$

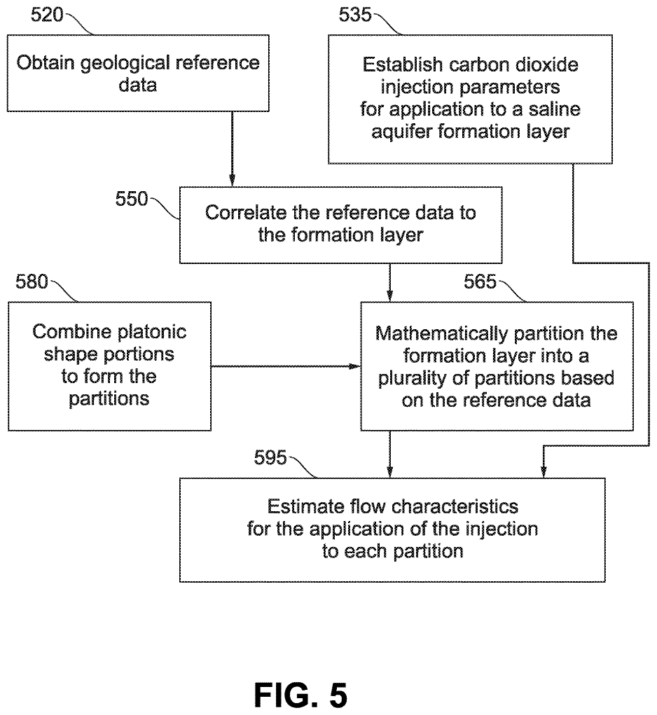

Referring now to FIG. 5, a flow-chart summarizing an embodiment of mathematically partitioning a saline aquifer formation layer to simulate injection of carbon dioxide into the formation layer is shown. As indicated at 520, geological reference data is obtained which may be correlatable to the saline aquifer formation layer in question. As noted above, this type of data may be obtained from prior readings during formation evaluation operations that include the aquifer formation layer or perhaps from other comparable sources such as analog or adjacent formations. Regardless, carbon dioxide injection parameters may be established as noted at 535 which are under consideration for simulating in terms of application to the saline aquifer formation layer. The method for global flowrate allocation across multiple discrete partitions involves assigning initial flowrates and then iteratively adjusting the allocation for each partition based on the pressure profile of the employed injection wells.

Before running the noted simulation, the indicated reference data may be applied to the formation layer as indicated at 550. For sake of quick and efficient computations, the reference data is uniquely applied to the formation layer. More specifically, as indicated at 565, the formation layer is mathematically partitioned into a plurality of partitions that are based on the reference data. Indeed, this partitioning may even include the combining of platonic shape portions to form the partitions (see 580) connecting the injection well or wells to boundaries of the system. Thus, readily available canonical shapes are relied upon in building the partitions. As a result, the estimating of flow characteristics for the proposed injection as shown at 595 may be carried out on a partition by partition basis in a more simplified and efficient manner so that a quick and reliable simulation may be obtained.

As indicated above, starting from the injection well, the reservoir is divided into multiple graphical partitions or chains. Given the total injection flow rate and known presumed boundary conditions, the flow rate allocation among different graphical chains may be modeled to ensure consistent pressure and saturation changes across the entire reservoir.

In one embodiment, this is achieved by the following:
1. Assume the reservoir is divided into N graphical chains. Assign an initial CO2 injection rate qⱼ (j=1, 2, . . . , N) to each graphical chain, with the constrains:

$${\sum }_{j = 1}^{N} {q}_{j} = {Q}_{T} \qquad ( 33 )$$

where Q_{T} is the total injection of CO2 at a given well/node.
2. Employing the techniques described above, calculate the pressure and CO₂ plume for each graphical chain.
3. Check whether the pressures at the injection well for each graphical chain are consistent. If they are not, redistribute the CO₂ injection rates qⱼ for each graphical chain and go back to step 2 here above; If yes, output the simulation results and exit the program.
   In this way, obtaining fast simulation results for CO₂ injection in a brine aquifer is attainable, even with various geological heterogeneity and different boundary conditions and in a manner that avoids resorting to a more complex, slower simulation model.

Embodiments of techniques are detailed herein that facilitate modeling of a saline aquifer in a practical matter that allows for the simulating of carbon dioxide injection into the aquifer. The techniques account for the fact that such aquifers are unlikely to be homogenous in terms of porosity and permeability characteristics, while at the same time rendering a practical and quick manner of simulation.

### ADDITIONAL CONSIDERATIONS

The preceding description has been presented with reference to presently preferred embodiments. Persons skilled in the art and technology to which these embodiments pertain will appreciate that alterations and changes in the described structures and methods of operation may be practiced without meaningfully departing from the principle, and scope of these embodiments. Regardless, the foregoing description should not be read as pertaining only to the precise structures described and shown in the accompanying drawings but rather should be read as consistent with and as support for the following claims, which are to have their fullest and fairest scope.

The various illustrative logical blocks, modules and circuits described in connection with the present disclosure may be implemented or performed with a general purpose processor, a digital signal processor (DSP), an application specific integrated circuit (ASIC), a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), or any other such configuration.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, “a processor,” “at least one processor,” or “one or more processors” generally refer to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory,” or “one or more memories” generally refer to a single memory configured to store data and/or instructions or multiple memories configured to collectively store data and/or instructions.

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an ASIC, or processor.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for”. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A method of simulating carbon dioxide injection into a saline aquifer, the method comprising:
obtaining geological reference data correlated to a saline aquifer formation layer;
establishing a set of carbon dioxide injection parameters for simulation;
mathematically partitioning the saline aquifer formation layer into a plurality of discrete partitions based on the geological reference data; and
estimating carbon dioxide flow characteristics for each discrete partition of the plurality based on the geological reference data and the carbon dioxide injection parameters.

2. The method of claim 1 wherein each of the discrete partitions radiate out from at least one injection well location of the saline aquifer formation layer.

3. The method of claim 1 wherein the carbon dioxide injection parameters include one of flowrate, duration, volume and pressure of injected carbon dioxide.

4. The method of claim 1 wherein the geological reference data correlated to the saline aquifer formation layer comprises one of permeability and porosity characteristics.

5. The method of claim 4 wherein the geological reference data comprises one of inferred logging data from an operation field including the saline aquifer formation layer and inferred data estimates based on comparable geological formations.

6. The method of claim 1 wherein the plurality of discrete partitions comprises a plurality of uniform angle tessellation partitions.

7. The method of claim 1 wherein at least one partition of the plurality of discrete partitions is a combination of platonic shape portions.

8. The method of claim 7 wherein each platonic shape portion is assigned its own characteristics of porosity and permeability.

9. The method of claim 7 wherein the estimating of the carbon dioxide flow characteristics includes computing carbon dioxide flow information across multiple interfacing platonic shape portions.

10. The method of claim 7 wherein the platonic shape portions are one of prism or cuboid shapes.

11. The method of claim 10 wherein the cuboid shapes are one of rectangular and trapezoidal shapes.

12. A method of simulating carbon dioxide injection into a saline aquifer, the method comprising:
obtaining geological reference data correlated to a saline aquifer formation layer;
establishing a set of carbon dioxide injection parameters for simulation of an application to at least one injection well in communication with the saline aquifer;
mathematically partitioning the saline aquifer formation layer into a plurality of discrete partitions based on the geological reference data;
plotting pseudo-node points of interest within one or more of the discrete partitions; and
estimating carbon dioxide flow characteristics for each discrete partition of the plurality based on the geological reference data and the carbon dioxide injection parameters, wherein the estimating includes ascertaining flow characteristics at the pseudo-node point of interest at a given point in time related to the carbon dioxide injection parameters.

13. The method of claim 12 wherein the discrete partitions are a combination of platonic shape portions.

14. The method of claim 12 wherein the estimating of the carbon dioxide flow characteristics comprises:
allocating flowrate across multiple discrete partitions of the plurality of partitions; and
iteratively adjusting the allocation for each partition of the plurality of partitions based on a pressure profile of the injection parameters for application to the at least one injection well.

15. The method of claim 12 wherein the carbon dioxide flow characteristic at the pseudo-node point of interest is one of pressure and carbon dioxide saturation.

16. The method of claim 15 wherein the one of the discrete partitions encompasses an abandoned well.

17. An operation field arrangement comprising:
an injection well at an operation field having a saline aquifer formation layer; and
a control unit for running a simulation of carbon dioxide injection into the aquifer, wherein the simulation includes obtaining geological reference data correlated to the saline aquifer formation layer and accounting for a set of carbon dioxide injection parameters for the simulation wherein the saline aquifer formation layer is mathematically partitioned into a plurality of discrete partitions based on the geological reference data for estimating carbon dioxide flow characteristics for each discrete partition of the plurality based on the geological reference data and the carbon dioxide injection parameters.

18. The operation field arrangement of claim 17 further comprising at least one abandoned well within at least one of the plurality of discrete partitions.

19. The operation field arrangement of claim 18 wherein the control unit is further configured to designate a pseudo-node point of interest within the at least one of the plurality of discrete portions with the at least one abandoned well.

20. The operation field arrangement of claim 19 wherein the carbon dioxide flow characteristic at the pseudo-node point of interest is one of pressure and carbon dioxide saturation.
